(19) United States
(12) Patent Application Publication
(10) Pub. No.: US 2025/0047121 A1
(43) Pub. Date: Feb. 6, 2025

(54) CHARGE CURRENT CUTOFF DETERMINATION BASED UPON LIFETIME BATTERY THROUGHPUTS

(71) Applicant: Iontra Inc, Centennial, CO (US)

(72) Inventor: Daniel A. KONOPKA, Denver, CO (US)

(21) Appl. No.: 18/792,471

(22) Filed: Aug. 1, 2024

Related U.S. Application Data
(60) Provisional application No. 63/530,179, filed on Aug. 1, 2023.

(51) Int. Cl. H02J 7/00; G01R 31/367; G01R 31/382

(52) U.S. Cl. CPC H02J 7/00714; G01R 31/367; G01R 31/382; H02J 7/007194

(57) ABSTRACT

Methods and systems are disclosed herein for charging a battery. Charging the battery includes altering charging of a battery when a charge current reaches a current cutoff value. The current cutoff value is based on an energy throughput of the battery. Altering charging may include terminating charge of the battery. The energy throughput of the battery may include charging and/or discharging. The current cutoff value may also be based on heat flux through the battery, where heat flux through the battery is determined using temperature measurements. The battery charging may include a constant current/constant voltage (CCCV) signal and/or a shaped charging signal.

### CROSS-REFERENCE TO RELATED APPLICATIONS

This application is related to and claims priority under 35 U.S.C. § 119(e) to U.S. Provisional Patent Application No. 63/530,179 filed Aug. 1, 2023, titled “Charge Current Cutoff Determination Based Upon Lifetime Battery Throughputs.”

### TECHNICAL FIELD

Embodiments of the present invention generally relate to systems and methods for charging a battery, and more specifically to a method of charging a battery where charging is altered, e.g., terminated, when a charge current reaches a current cutoff value that is based on some measure of energy into and out of the battery during charge and discharge, which may not be full charge and discharge cycle of the battery, and/or a measure of heat flux during charge and discharge, either or both of which are assessed over some measure of the life of the battery preceding the charge cycle.

### BACKGROUND AND INTRODUCTION

Countless different types of electrically powered devices, such as power tools, mobile computing and communication devices, portable electronic devices, and electrically powered vehicles of all sorts including scooters and bicycles, use rechargeable batteries as a source of operating power. Rechargeable batteries are limited by finite battery capacity and must be recharged upon depletion. Recharging a battery may be inconvenient as the powered device must often be stationary during the time required for recharging the battery. Depending on battery size, recharging can take hours. Moreover, battery charging is often accompanied by degradation of battery performance. As such, significant effort has been put into developing battery charging technology to reduce the time needed to recharge the battery, improve battery performance, reduce degradation of the battery from charging, among other things.

It is with these observations in mind, among others, that various aspects of the present disclosure were conceived and developed.

### BRIEF DESCRIPTION OF THE DRAWINGS

Various objects, features, and advantages of the present disclosure will be discussed in the following description of embodiments of those inventive concepts. The following figures accompany the description to clarify certain concepts of this disclosure. It should be noted that the drawings are not necessarily to scale, may not include every detail, and may be representative of various features of an embodiment. The primary emphasis of the drawings is to illustrate principles and other aspects of the inventive concepts. Also, in the drawings like reference characters may refer to the same parts or similar throughout the different views. It is intended that the embodiments and figures disclosed herein are to be considered illustrative rather than limiting.

FIG. 1 is a plot showing average charging current cutoff values versus lifetime energy throughput, in accordance with embodiments herein.

FIG. 2 is a diagram depicting non-constant voltage charge signal with a shaped leading edge, body portion and rest period.

FIG. 3 is a diagram illustrating an example of a computing system which may be used in implementing embodiments of the present disclosure.

### DETAILED DESCRIPTION

Aspects of the present disclosure involve a method of charging a battery where charging is altered, which may involve terminating charge, reducing charge current or some other change, when a current cutoff value is reached. The method of terminating the charge process for a battery, which may comprise a discrete battery cell, pack of such cells, etc., uses a variable current cutoff value (Amps) referenced as a function of some measure of energy throughput (which may be during charge, during discharge, or both), which measure of energy throughput may involve total lifetime power, energy, or capacity throughput. The current cut-off value may be further based on a measure of heat flux, which may be total lifetime heat flux based upon temperature measurements over time.

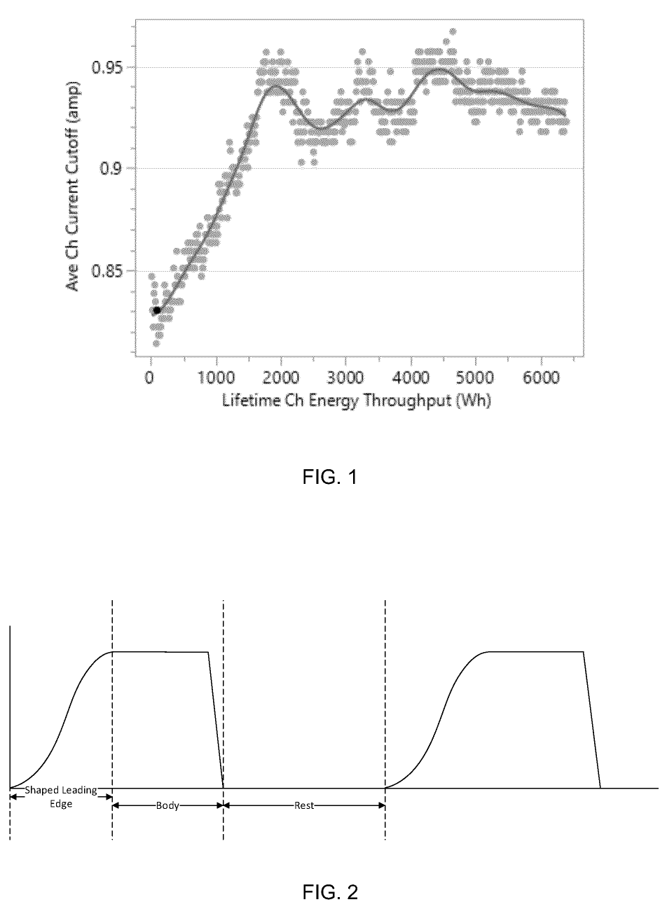

In one possible specific arrangement, during a constant voltage (CV) period of a constant current constant voltage (CCCV) type charge sequence of a battery, the appropriate current cutoff value may be referenced from a formula or lookup table or similar (e.g., based on FIG. 1). In such a charging arrangement, the battery is charged first under a constant current (CC) period of charge until a battery terminal voltage rises to some threshold, which is typically battery dependent, and then transitions to a constant voltage sequence of charging. The constant current portion of the charge may include other forms of charging, alone or in combination with constant voltage charging. In the constant voltage portion of the charge, the charging system seeks to maintain the terminal voltage at a constant level, which may be the threshold voltage that initiated the transition to constant voltage charging. In the constant voltage portion, because the battery is reaching nearly full capacity (e.g., 100% SOC), the voltage will tend to rise but to maintain the constant voltage, the charge current is steadily reduced. However, instead of terminating charge when the charge current drops below some threshold, which is typically a fixed threshold based on some safety margin intended to avoid overcharging but is not dynamic, as a battery reaches a full state of charge as used in conventional CCCV charging, here the system may define a variable current cutoff threshold which changes as a battery or battery pack ages with increasing lifetime energy throughput. In one example, the charge current cutoff is not a measure of the charge current at some point in time but rather charge is terminated based on charge throughput and/or heat flux or other parameters as discussed below.

So, for example, the variable current cutoff can dynamically adjust to aging of the battery and reduced capacity associated with the number of charge and discharge cycles. In some cases, a battery may be charged for a longer period early in life thereby providing greater capacity, and adjust to capacity decreases dynamically without damaging the battery by overcharging as the battery ages. The system may also accommodate and adjust the end of charge sequence to accommodate different possible periods where the battery experiences heat flux, which can also age the battery differently from normal temperature charging and effect battery capacity. These and other advantages may be realized by various aspects of the present disclosure.

More than one reference may be used along with some algorithmic interpretation in order to determine the appropriate current cutoff value. For example, total lifetime capacity (Ah) may be a reliable reference under fixed charge, discharge and environmental conditions because the cell ages in a specific manner. However, real-world applications may involve variable charge and discharge rates and environmental conditions which are different from ideal benchmarking. In this case, parameters which more closely reflect aging of the battery, such as power (watts) and heat flux (temperature and time) may be more appropriate as an aging reference with regard to appropriate current cutoff values. As batteries age, and as internal impedance increases, more power may be required to charge to completion, with more heat generated during the process. Similarly, during discharge, an aging battery may support less power output while simultaneously generating increased levels of heat. In an implementation accommodating more than one reference parameter, each reference parameter may be assigned a weighting, rank or similar in the evaluation of multiple metrics to determine a single current cutoff value.

As implied above, reference metrics may be tracked and evaluated separately for charge and discharge processes, as a simple means of assessing battery condition and the appropriate current cutoff value. The relationship between optimal current cutoff value and one or more reference parameters may be determined empirically, via modeling, or any or means of identifying causality between the two.

In the example of a CV portion for a charge cycle, the method involves charging at a constant voltage and altering charge, e.g., terminating charge, when the current cutoff value is reached and where the current cutoff value is based on some measure of energy throughput, which may be lifetime energy throughput, and/or some measure of heat flux, which may similarly be lifetime heatflux. While terminating charge based on the current cutoff is one possible implementation, the system may alter charge, initiate a rest period, or take some other action upon reaching the current cutoff value.

In some cases, the charge signal may be shaped and/or may include a plurality of repeating waveforms, as shown in FIG. 2. For example, during a period prior to an end of charge constant voltage period, instead of a constant current period, the system may employ a charge signal with repeating waveforms, and transition to a constant voltage period based on some measure. Here, the charge signal has a waveform with a shaped leading edge, where charge current increases to a body portion where charge current may be held constant for some period, followed by a falling edge and a rest period. The shaped leading edge may follow the shape of sinusoid. The charge signal may also take advantage of the charge current cutoff without transitioning to a constant voltage portion. For example, in the case of such a shaped charging signal, the method may average the charge current across the active part of the charge signal (e.g., the shaped leading edge and body portions) or may average the charge current across the active part of the charge signal and the rest period or may take some other measure of charge current, and compare it to the current cutoff threshold based on energy and or heat flux throughput, and alter (e.g., terminate) charging based on when that measure of charge current meets the current cutoff.

This method will retain effectiveness in real world conditions when cells or packs are charged and/or discharged partially, rather than to completion. In this scenario, charging and discharging parameters cannot be determined by referencing a total cycle count and this represents a problematic difference between laboratory and real-world use cases.

The plot of FIG. 1 shows a consistent and variable relationship between the ideal constant voltage current cutoff value (amps) as a function of total lifetime charge energy throughput from the battery's beginning of life. The information was empirically determined based upon ideal cycling performance from a 21700 Lithium-Ion battery cell rechargeable, 3.6/3.7 nominal voltage with a 4.2 V charge voltage. The solid line in the plot may serve as the current cutoff determination to ensure consistent lifetime performance with new cells of the same type. So, here, when charging a 21700 cell at a constant voltage and the cell has experienced some amount of lifetime energy throughput (e.g., a value plotted on the x-axis), charge will terminate when a current cutoff value (e.g., the associated y-axis value) is reached based on the lifetime energy throughput of the particular battery being charged.

The plot of FIG. 1 shows current cutoff values versus lifetime energy throughput of 21700 Lithium-Ion battery cells that were charged for some fixed period of time and charge was terminated at the same fixed period of time for the cells. For the batteries used to generate the plot, charge was not terminated based on some fixed current level typically associated with CCCV type charging. As a result, charging was typically terminated at a higher current level than typically associated with CCCV charging (e.g., charge was terminated prior to when charge would have been terminated using a conventional CCCV charge). The technique results in a longer capacity life of the cell while maintain or allowing for increased charge rates.

In this example, a charging system will include a measure of energy throughput and a table with values for charge current cutoff and energy throughput. During a charge cycle, the charge current cutoff value is set based on the energy throughput for that charge cycle. In the CV portion discussed above, charge will terminate when the charge current falls to the charge current cutoff value set from the table. The table may be stored locally or accessed remotely by way of some network connection.

Charge cutoff values may also be accessed from a table with heat flux versus charge current cutoff. In such an implementation, the system measures or computes heat flux, and accesses a charge current cutoff based on total heatflux up to the current charge cycle. In a system where the two values (heat flux and energy throughput) are used in combination, the system may use the higher of the two charge current cutoff values, and average of the two values, or some other combination of the two values. For any particular charge cycle, the system may also prefer the charge current cutoff value from one value over the other based on some other metric including the number of charge cycles, the degree of heat flux or the like.

The term “battery” in the art and herein can be used in various ways and may refer to an individual cell having an anode and cathode separated by an electrolyte, solid or liquid, as well as a collection of such cells connected in various arrangements. A battery or battery cell is a form of electrochemical device. Batteries generally comprise repeating units of sources of a countercharge and electrode layers separated by an ionically conductive barrier, often a liquid or polymer membrane saturated with an electrolyte. These layers are made to be thin so multiple units can occupy the volume of a battery, increasing the available power of the battery with each stacked unit. Although many examples are discussed herein as applicable to a battery, it should be appreciated that the systems and methods described may apply to many different types of batteries ranging from an individual cell to batteries involving different possible interconnections of cells such as cells coupled in parallel, series, and parallel and series. For example, the systems and methods discussed herein may apply to a battery pack comprising numerous cells arranged to provide a defined pack voltage, output current, and/or capacity. Moreover, the implementations discussed herein may apply to different types of electrochemical devices such as various different types of lithium batteries including but not limited to lithium-metal and lithium-ion batteries, lead-acid batteries, various types of nickel batteries, and solid-state batteries of various possible chemistries, to name a few. The various implementations discussed herein may also apply to different structural battery arrangements such as button or “coin” type batteries, cylindrical cells, pouch cells, and prismatic cells.

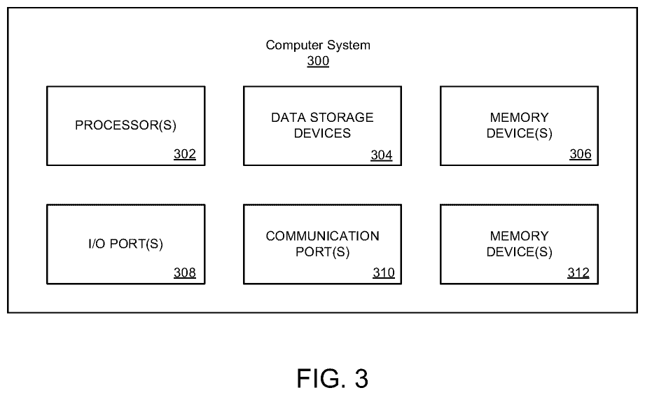

Referring to FIG. 3, a detailed description of an example computing system 300 having one or more computing units that may implement various systems and methods discussed herein is provided. The computing system 300 may be part of a controller, may be in operable communication with various implementation discussed herein, may run various operations related to the method discussed herein, may run offline to process various data for characterizing a battery, and may be part of overall systems discussed herein. The computing system 300 may process various signals discussed herein and/or may provide various signals discussed herein. For example, battery measurement information may be provided to such a computing system 300. The computing system 300 may also be applicable to, for example, the controller, the model, the tuning/shaping circuits discussed with respect to the various figures and may be used to implement the various methods described herein. It will be appreciated that specific implementations of these devices may be of differing possible specific computing architectures, not all of which are specifically discussed herein but will be understood by those of ordinary skill in the art. It will further be appreciated that the computer system may be considered and/or include an ASIC, FPGA, microcontroller, or other computing arrangement. In such various possible implementations, more or fewer components discussed below may be included, interconnections and other changes made, as will be understood by those of ordinary skill in the art.

The computer system 300 may be a computing system that is capable of executing a computer program product to execute a computer process. Data and program files may be input to the computer system 300, which reads the files and executes the programs therein. Some of the elements of the computer system 300 are shown in FIG. 3, including one or more hardware processors 302, one or more data storage devices 304, one or more memory devices 306, and/or one or more ports 308-312. Additionally, other elements that will be recognized by those skilled in the art may be included in the computing system 300 but are not explicitly depicted in FIG. 3 or discussed further herein. Various elements of the computer system 300 may communicate with one another by way of one or more communication buses, point-to-point communication paths, or other communication means not explicitly depicted in FIG. 3. Similarly, in various implementations, various elements disclosed in the system may or not be included in any given implementation.

The processor 302 may include, for example, a central processing unit (CPU), a microprocessor, a microcontroller, a digital signal processor (DSP), and/or one or more internal levels of cache. There may be one or more processors 302, such that the processor 302 comprises a single central-processing unit, or a plurality of processing units capable of executing instructions and performing operations in parallel with each other, commonly referred to as a parallel processing environment.

The presently described technology in various possible combinations may be implemented, at least in part, in software stored on the data stored device(s) 304, stored on the memory device(s) 306, and/or communicated via one or more of the ports 308-312, thereby transforming the computer system 300 in FIG. 3 to a special purpose machine for implementing the operations described herein.

The one or more data storage devices 304 may include any non-volatile data storage device capable of storing data generated or employed within the computing system 300, such as computer executable instructions for performing a computer process, which may include instructions of both application programs and an operating system (OS) that manages the various components of the computing system 300. The data storage devices 304 may include, without limitation, magnetic disk drives, optical disk drives, solid state drives (SSDs), flash drives, and the like. The data storage devices 304 may include removable data storage media, non-removable data storage media, and/or external storage devices made available via a wired or wireless network architecture with such computer program products, including one or more database management products, web server products, application server products, and/or other additional software components. Examples of removable data storage media include Compact Disc Read-Only Memory (CD-ROM), Digital Versatile Disc Read-Only Memory (DVD-ROM), magneto-optical disks, flash drives, and the like. Examples of non-removable data storage media include internal magnetic hard disks, SSDs, and the like. The one or more memory devices 306 may include volatile memory (e.g., dynamic random-access memory (DRAM), static random access memory (SRAM), etc.) and/or non-volatile memory (e.g., read-only memory (ROM), flash memory, etc.).

Computer program products containing mechanisms to effectuate the systems and methods in accordance with the presently described technology may reside in the data storage devices 304 and/or the memory devices 306, which may be referred to as machine-readable media. It will be appreciated that machine-readable media may include any tangible non-transitory medium that is capable of storing or encoding instructions to perform any one or more of the operations of the present disclosure for execution by a machine or that is capable of storing or encoding data structures and/or modules utilized by or associated with such instructions. Machine-readable media may include a single medium or multiple media (e.g., a centralized or distributed database, and/or associated caches and servers) that store the one or more executable instructions or data structures.

In some implementations, the computer system 300 includes one or more ports, such as an input/output (I/O) port 308, a communication port 310, and a sub-systems port 312, for communicating with other computing, network, or vehicle devices. It will be appreciated that the ports 308-312 may be combined or separate and that more or fewer ports may be included in the computer system 300. The I/O port 308 may be connected to an I/O device, or other device, by which information is input to or output from the computing system 300. Such I/O devices may include, without limitation, one or more input devices, output devices, and/or environment transducer devices.

In one implementation, the input devices convert a human-generated signal, such as, human voice, physical movement, physical touch or pressure, and/or the like, into electrical signals as input data into the computing system 300 via the I/O port 308. In some examples, such inputs may be distinct from the various system and method discussed with regard to the preceding figures. Similarly, the output devices may convert electrical signals received from computing system 300 via the I/O port 308 into signals that may be sensed or used by the various methods and system discussed herein. The input device may be an alphanumeric input device, including alphanumeric and other keys for communicating information and/or command selections to the processor 302 via the I/O port 308.

The environment transducer devices convert one form of energy or signal into another for input into or output from the computing system 300 via the I/O port 308. For example, an electrical signal generated within the computing system 300 may be converted to another type of signal, and/or vice-versa. In one implementation, the environment transducer devices sense characteristics or aspects of an environment local to or remote from the computing device 300, such as battery voltage, open circuit battery voltage, charge current, battery temperature, light, sound, temperature, pressure, magnetic field, electric field, chemical properties, and/or the like.

In one implementation, a communication port 310 may be connected to a network by way of which the computer system 300 may receive network data useful in executing the methods and systems set out herein as well as transmitting information and network configuration changes determined thereby. For example, charging protocols may be updated, battery measurement or calculation data shared with external system, and the like. The communication port 310 connects the computer system 300 to one or more communication interface devices configured to transmit and/or receive information between the computing system 300 and other devices by way of one or more wired or wireless communication networks or connections. Examples of such networks or connections include, without limitation, Universal Serial Bus (USB), Ethernet, Wi-Fi, Bluetooth®, Near Field Communication (NFC), Long-Term Evolution (LTE), and so on. One or more such communication interface devices may be utilized via the communication port 310 to communicate with one or more other machines, either directly over a point-to-point communication path, over a wide area network (WAN) (e.g., the Internet), over a local area network (LAN), over a cellular (e.g., third generation (3G), fourth generation (4G), fifth generation (5G)) network, or over another communication means.

The computer system 300 may include a sub-systems port 312 for communicating with one or more systems related to a device being charged according to the methods and system described herein to control an operation of the same and/or exchange information between the computer system 300 and one or more sub-systems of the device. Examples of such sub-systems of a vehicle, include, without limitation, motor controllers and systems, battery control systems, and others.

The system set forth in FIG. 3 is but one possible example of a computer system that may employ or be configured in accordance with aspects of the present disclosure. It will be appreciated that other non-transitory tangible computer-readable storage media storing computer-executable instructions for implementing the presently disclosed technology on a computing system may be utilized.

Embodiments of the present disclosure include various steps, which are described in this specification. The steps may be performed by hardware components or may be embodied in machine-executable instructions, which may be used to cause a general-purpose or special-purpose processor programmed with the instructions to perform the steps. Alternatively, the steps may be performed by a combination of hardware, software and/or firmware.

Various modifications and additions can be made to the exemplary embodiments discussed without departing from the scope of the present invention. For example, while the embodiments, also referred to as implementations or examples, described above refer to particular features, the scope of this invention also includes embodiments having different combinations of features and embodiments that do not include all of the described features. Accordingly, the scope of the present invention is intended to embrace all such alternatives, modifications, and variations together with all equivalents thereof.

While specific implementations are discussed, it should be understood that this is done for illustration purposes only. A person skilled in the relevant art will recognize that other components and configurations may be used without parting from the spirit and scope of the disclosure. Thus, the following description and drawings are illustrative and are not to be construed as limiting. Numerous specific details are described to provide a thorough understanding of the disclosure. However, in certain instances, well-known or conventional details are not described in order to avoid obscuring the description. References to one or an embodiment in the present disclosure can be references to the same embodiment or any embodiment; and, such references mean at least one of the embodiments.

Reference to “one embodiment” or “an embodiment” means that a particular feature, structure, or characteristic described in connection with the embodiment is included in at least one embodiment of the disclosure. The appearances of the phrase “in one embodiment”, or similarly “in one example” or “in one instance”, in various places in the specification are not necessarily all referring to the same embodiment, nor are separate or alternative embodiments mutually exclusive of other embodiments. Moreover, various features are described which may be exhibited by some embodiments and not by others.

The terms used in this specification generally have their ordinary meanings in the art, within the context of the disclosure, and in the specific context where each term is used. Alternative language and synonyms may be used for any one or more of the terms discussed herein, and no special significance should be placed upon whether or not a term is elaborated or discussed herein. In some cases, synonyms for certain terms are provided. A recital of one or more synonyms does not exclude the use of other synonyms. The use of examples anywhere in this specification including examples of any terms discussed herein is illustrative only and is not intended to further limit the scope and meaning of the disclosure or of any example term. Likewise, the disclosure is not limited to various embodiments given in this specification.

Without intent to limit the scope of the disclosure, examples of instruments, apparatus, methods and their related results according to the embodiments of the present disclosure are given below. Note that titles or subtitles may be used in the examples for convenience of a reader, which in no way should limit the scope of the disclosure. Unless otherwise defined, technical and scientific terms used herein have the meaning as commonly understood by one of ordinary skill in the art to which this disclosure pertains. In the case of conflict, the present document, including definitions will control.

Additional features and advantages of the disclosure will be set forth in the description which follows, and in part will be obvious from the description, or can be learned by practice of the herein disclosed principles. The features and advantages of the disclosure can be realized and obtained by means of the instruments and combinations particularly pointed out in the appended claims. These and other features of the disclosure will become more fully apparent from the following description and appended claims or can be learned by the practice of the principles set forth herein.

What is claimed is:

1. A method of charging a battery comprising:
altering charging of a battery when a charge current reaches a current cutoff value, the current cutoff value based on an energy throughput of the battery.

2. The method of claim 1 wherein altering charging of the battery comprises terminating charging of the battery.

3. The method of claim 1 wherein the energy throughput of the battery comprises a measure of energy throughput during charge and discharge of the battery over time.

4. The method of claim 3 wherein the measure of energy throughput during charge and discharge is over all preceding charge and discharge cycles.

5. The method of claim 1 wherein the energy throughput of the battery comprises at least one of a measure of energy throughput, a measure of power throughput, or a measure of capacity throughput.

6. The method of claim 1 further comprising accessing the current cutoff from a table correlating a charge current termination with lifetime energy throughput for a collection of batteries of the same type as the battery being charged.

7. The method of claim 1, wherein the current cutoff value is further based on a measure of heat flux through the battery.

8. The method of claim 7, wherein the measure of heat flux comprises a total lifetime heat flux.

9. The method of claim 7, wherein the measure of heat flux is based on battery temperature measurements.

10. The method of claim 1, wherein the current cutoff value is determined using a model based on energy throughput of the battery.

11. The method of claim 10, wherein the model is further based on heat flux through the battery.

12. The method of claim 11, wherein the energy throughput of the battery and the heat flux through the battery are weighted references within the model.

13. The method of claim 1, wherein the charging of the battery comprises a constant voltage charging signal where the charge current is reduced to maintain a battery voltage, and the charge current is terminated upon reaching a charge current value matching the charge current cutoff value.

14. The method of claim 1, wherein the charging of the battery comprises applying a shaped charging signal to the battery, wherein the shaped charging signal comprises a repeating waveform having a shaped leading edge.

15. The method of claim 14, further comprising:
determining an average current over the shaped charging signal; and
comparing the average current to the current cutoff value.

16. The method of claim 15, wherein determining the average current over the shaped charging signal comprises averaging current over the shaped leading edge, a body portion, and a rest portion of the shaped charging signal.

17. The method of claim 16, wherein determining the average current over the shaped charging signal comprises averaging current over the shaped leading edge and the body portion.

18. The method of claim 1, wherein the current cutoff value has a non-linear relationship with lifetime energy throughput.

19. The method of claim 1, wherein the current cutoff value oscillates over a range of lifetime energy throughput.
